(19) United States
(12) Patent Application Publication
(10) Pub. No.: US 2025/0247062 A1
(43) Pub. Date: Jul. 31, 2025

(54) APPARATUS AND METHODS FOR POWER AMPLIFIER RUGGEDNESS PROTECTION

(71) Applicant: Skyworks Solutions, Inc., Irvine, CA (US)

(72) Inventors: Pietro Natale Alessandro Chyurlia, Ottawa (CA); Daniel Jerome Eastman, Ottawa (CA); Cagatay Ozmen, North Andover, MA (US)

(21) Appl. No.: 19/039,468

(22) Filed: Jan. 28, 2025

Related U.S. Application Data
(60) Provisional application No. 63/627,478, filed on Jan. 31, 2024.
(60) Provisional application No. 63/627,433, filed on Jan. 31, 2024.

(51) Int. Cl. H03F 3/24; H04B 1/40

(52) U.S. Cl. CPC H03F 3/245; H04B 1/40; H03F 2200/294; H03F 2200/451

(57) ABSTRACT

Apparatus and methods for power amplifier ruggedness protection are disclosed. In certain embodiments, a power amplifier system includes a power amplifier, a power amplifier bias circuit that biases the power amplifier with two or more bias signals, and a reference signal generator that generates two or more reference signals for the power amplifier bias circuit. The power amplifier bias circuit uses a first reference signal of the reference signals to bias an input stage of the power amplifier and a second reference signal to bias another stage of the power amplifier (for instance, an output stage or an intermediate stage between the input stage and the output stage). The power amplifier system further includes a power detector that generates a detection signal based on sensing an RF input signal to the input stage. The power detector is selectively enabled (turned on or off) using the second reference signal.

### CROSS-REFERENCE TO RELATED APPLICATIONS

This application claims the benefit of priority under 35 U.S.C. § 119 of U.S. Provisional Patent Application No. 63/627,478, filed Jan. 31, 2024 and titled “APPARATUS AND METHODS FOR POWER AMPLIFIER RUGGEDNESS PROTECTION,” and of U.S. Provisional Patent Application No. 63/627,433, filed Jan. 31, 2024 and titled “APPARATUS AND METHODS FOR LOW NOISE AMPLIFIER RUGGEDNESS PROTECTION,” each of which is herein incorporated by reference in its entirety.

### BACKGROUND

### Field

Embodiments of the invention relate to electronic systems, and in particular, to radio frequency electronics.

### Description of Related Technology

Radio frequency (RF) communication systems can be used for transmitting and/or receiving signals. An RF communication system can be used to wirelessly communicate RF signals, which have a frequency in the range of 30 kHz to 300 GHz. For example, in a cellular application, RF signals can have a frequency in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard. Additionally, in a Wi-Fi application, the Wi-Fi 2.4GHz frequency band spans from about 2.401 GHz to about 2.473 GHz, while the Wi-Fi 5GHz frequency band spans from about 5.170 GHz to about 5.895 GHz and the Wi-Fi 6GHz frequency band spans from about 5.945 GHz to about 7.125 GHz.

Examples of RF communication systems include, but are not limited to, mobile phones, tablets, base stations, network access points, customer-premises equipment (CPE), laptops, wireless routers, and wearable electronics.

### SUMMARY

In certain embodiments, the present disclosure relates to a mobile device. The mobile device includes a transceiver configured to generate a radio frequency input signal, and a front-end system including a power amplifier configured to amplify the radio frequency input signal and that includes a first stage biased by a first bias signal and a second stage biased by a second bias signal. The front-end system further includes a reference signal generator configured to generate a first reference signal and a second reference signal, a power amplifier bias circuit configured to generate the first bias signal based on the first reference signal and the second bias signal based on the second reference signal, and a power detector that generates a detection signal based on sensing a power of the radio frequency input signal, the power detector selectively enabled by the second reference signal.

In various embodiments, the power amplifier bias circuit disables at least one stage of the power amplifier in response to activation of the detection signal to provide ruggedness protection.

In several embodiments, the power amplifier is operable in a plurality of operating modes, and the power amplifier bias circuit processes the detection signal to set an operating mode of the power amplifier to a selected operating mode chosen from the plurality of operating modes.

In some embodiments, the first stage is an input stage. According to a number of embodiments, the second stage is an output stage. In accordance with various embodiments, the second stage is an intermediate stage connected between the input stage and an output stage of the power amplifier.

In various embodiments, the power amplifier bias circuit includes a pull-down transistor configured to pull-down at least one of the first bias signal or the second bias signal in response to activation of the detection signal.

In several embodiments, the power detector activates the detection signal in response to the power of the radio frequency input signal exceeding a power threshold.

In some embodiments, a value of the power threshold changes with temperature to provide temperature compensation. According to a number of embodiments, a value of the power threshold changes with a supply voltage of the power amplifier to provide supply voltage compensation.

In various embodiments, the reference signal generator includes a first current source configured to generate the first reference signal as a first reference current and a second current source configured to generate the second reference signal as a second reference current.

In several embodiments, the power detector includes a detection circuit configured to receive a portion of the radio frequency input signal and to output the detection signal, and a gating circuit connected between the power detector and a ground voltage and configured to open or close based on the second reference signal.

In various embodiments, the power amplifier further includes a third stage biased by a third bias signal, the reference signal generator is further configured to generate a third reference signal, and the power amplifier bias circuit is further configured to generate the third bias signal based on the third reference signal. According to a number of embodiments, the first stage is an input stage, the second stage is an output stage, and the third stage is an intermediate stage connected between the input stage and the output stage. In accordance with several embodiments, the first stage is an input stage, the third stage is an output stage, and the second stage is an intermediate stage connected between the input stage and the output stage.

In some embodiments, the front-end system includes a capacitor configured to couple a portion of the radio frequency input signal to an input of the power detector.

In various embodiments, the front-end system includes an input splitter having an input configured to receive the radio frequency input signal, a first output that provides a first output signal to an input of the power detector, and a second output that provides a second output signal to the first stage of the power amplifier.

In several embodiments, the front-end system further includes a memory element configured to receive the detection signal.

In some embodiments, the front-end system further includes a switch controlled by the detection signal.

In various embodiments, the power amplifier bias circuit receives the detection signal.

In several embodiments, the front-end system further includes a mode control circuit configured to receive the detection signal.

In some embodiments, the front-end system further includes a flag detector configured to receive the detection signal.

In certain embodiments, the present disclosure relates to a method of power detection in a power amplifier system. The method includes amplifying a radio frequency input signal using a power amplifier that includes a first stage biased by a first bias signal and a second stage biased by a second bias signal, generating a first reference signal and a second reference signal using a reference signal generator, generating the first bias signal based on the first reference signal and generating the second bias signal based on the second reference signal using a bias circuit, generating a detection signal based on sensing a power of the radio frequency input signal using a power detector, and selectively enabling the power detector using the second reference signal.

In various embodiments, the method further includes using the bias circuit to disable at least one stage of the power amplifier in response to activation of the detection signal to provide ruggedness protection.

In several embodiments, the power amplifier is operable in a plurality of operating modes, the method further including processing the detection signal to set an operating mode of the power amplifier to a selected operating mode chosen from the plurality of operating modes.

In some embodiments, the first stage is an input stage. According to a number of embodiments, the second stage is an output stage. In accordance with several embodiments, the second stage is an intermediate stage connected between the input stage and an output stage. According to various embodiments, the method further includes using a pull-down transistor to pull-down at least one of the first bias signal or the second bias signal in response to activation of the detection signal.

In several embodiments, the method further includes using the power detector to activate the detection signal in response to the power of the radio frequency input signal exceeding a power threshold. According to a number of embodiments, a value of the power threshold changes with temperature to provide temperature compensation. In accordance with various embodiments, a value of the power threshold changes with a supply voltage of the power amplifier to provide supply voltage compensation.

In some embodiments, the reference signal generator includes a first current source configured to generate the first reference signal as a first reference current and a second current source configured to generate the second reference signal as a second reference current.

In various embodiments, the power detector includes a detection circuit configured to receive a portion of the radio frequency input signal and to output the detection signal, and a gating circuit connected between the power detector and a ground voltage and configured to open or close based on the second reference signal.

In several embodiments, the power amplifier further includes a third stage biased by a third bias signal, the method further including generating a third reference signal using the reference signal generator, and generating the third bias signal based on the third reference signal using the bias circuit. According to various embodiments, the first stage is an input stage, the second stage is an output stage, and the third stage is an intermediate stage connected between the input stage and the output stage. In accordance with some embodiments, the first stage is an input stage, the third stage is an output stage, and the second stage is an intermediate stage connected between the input stage and the output stage.

In various embodiments, the method further includes using a capacitor to couple a portion of the radio frequency input signal to an input of the power detector.

In several embodiments, the method further includes using an input splitter to couple a portion of the radio frequency input signal to an input of the power detector.

In some embodiments, the method further includes receiving the detection signal as an input to a memory element.

In several embodiments, the method further includes controlling a switch based on the detection signal.

In some embodiments, the method further includes receiving the detection signal as an input to the bias circuit.

In various embodiments, the method further includes receiving the detection signal as an input to a mode control circuit.

In several embodiments, the method further includes receiving the detection signal as an input to a flag detector.

In certain embodiments, the present disclosure relates to a power amplifier system. The power amplifier system includes a power amplifier configured to amplify a radio frequency input signal, the power amplifier including a first stage biased by a first bias signal and a second stage biased by a second bias signal. The power amplifier system further includes a reference signal generator configured to generate a first reference signal and a second reference signal, a bias circuit configured to generate the first bias signal based on the first reference signal and the second bias signal based on the second reference signal, and a power detector that generates a detection signal based on sensing a power of the radio frequency input signal, the power detector selectively enabled by the second reference signal.

In some embodiments, the bias circuit disables at least one stage of the power amplifier in response to activation of the detection signal to provide ruggedness protection.

In various embodiments, the power amplifier is operable in a plurality of operating modes, and the bias circuit processes the detection signal to set an operating mode of the power amplifier to a selected operating mode chosen from the plurality of operating modes.

In several embodiments, the first stage is an input stage. According to some embodiments, the second stage is an output stage. In accordance with various embodiments, the second stage is an intermediate stage connected between the input stage and an output stage.

In some embodiments, the bias circuit includes a pull-down transistor configured to pull-down at least one of the first bias signal or the second bias signal in response to activation of the detection signal.

In various embodiments, the power detector activates the detection signal in response to the power of the radio frequency input signal exceeding a power threshold. According to a number of embodiments, a value of the power threshold changes with temperature to provide temperature compensation. In accordance with several embodiments, a value of the power threshold changes with a supply voltage of the power amplifier to provide supply voltage compensation.

In some embodiments, the reference signal generator includes a first current source configured to generate the first reference signal as a first reference current and a second current source configured to generate the second reference signal as a second reference current.

In various embodiments, the power detector includes a detection circuit configured to receive a portion of the radio frequency input signal and to output the detection signal, and a gating circuit connected between the power detector and a ground voltage and configured to open or close based on the second reference signal.

In several embodiments, the power amplifier further includes a third stage biased by a third bias signal, the reference signal generator is further configured to generate a third reference signal, and the bias circuit is further configured to generate the third bias signal based on the third reference signal. In accordance with a number of embodiments, the first stage is an input stage, the second stage is an output stage, and the third stage is an intermediate stage connected between the input stage and the output stage. According to some embodiments, the first stage is an input stage, the third stage is an output stage, and the second stage is an intermediate stage connected between the input stage and the output stage.

In various embodiments, the power amplifier system further includes a capacitor configured to couple a portion of the radio frequency input signal to an input of the power detector.

In some embodiments, the power amplifier system further includes an input splitter having an input configured to receive the radio frequency input signal, a first output that provides a first output signal to an input of the power detector, and a second output that provides a second output signal to the first stage of the power amplifier.

In several embodiments, the power amplifier system further includes a memory element configured to receive the detection signal.

In various embodiments, the power amplifier system further includes a switch controlled by the detection signal.

In some embodiments, the bias circuit receives the detection signal.

In several embodiments, the power amplifier system further includes a mode control circuit configured to receive the detection signal.

In various embodiments, the power amplifier system further includes a flag detector configured to receive the detection signal.

In certain embodiments, the present disclosure relates to a mobile device. The mobile device includes an antenna configured to generate a radio frequency input signal in response to receiving a radio wave, and a front-end system including a low noise amplifier configured to amplify the radio frequency input signal and that includes a first stage biased by a first bias signal and a second stage biased by a second bias signal. The front-end system further includes a reference signal generator configured to generate a first reference signal and a second reference signal, a low noise amplifier bias circuit configured to generate the first bias signal based on the first reference signal and the second bias signal based on the second reference signal, and a power detector that generates a detection signal based on sensing a power of the radio frequency input signal, the power detector selectively enabled by the second reference signal.

In various embodiments, the low noise amplifier bias circuit disables at least one stage of the low noise amplifier in response to activation of the detection signal to provide ruggedness protection.

In several embodiments, the low noise amplifier is operable in a plurality of operating modes, and the low noise amplifier bias circuit processes the detection signal to set an operating mode of the low noise amplifier to a selected operating mode chosen from the plurality of operating modes.

In some embodiments, the first stage is an input stage. According to a number of embodiments, the second stage is an output stage. In accordance with several embodiments, the second stage is an intermediate stage connected between the input stage and an output stage of the low noise amplifier.

In various embodiments, the low noise amplifier bias circuit includes a pull-down transistor configured to pull-down at least one of the first bias signal or the second bias signal in response to activation of the detection signal.

In several embodiments, the power detector activates the detection signal in response to the power of the radio frequency input signal exceeding a power threshold. According to a number of embodiments, a value of the power threshold changes with temperature to provide temperature compensation. In accordance with various embodiments, a value of the power threshold changes with a supply voltage of the low noise amplifier to provide supply voltage compensation.

In various embodiments, the reference signal generator includes a first current source configured to generate the first reference signal as a first reference current and a second current source configured to generate the second reference signal as a second reference current.

In some embodiments, the power detector includes a detection circuit configured to receive a portion of the radio frequency input signal and to output the detection signal, and a gating circuit connected between the power detector and a ground voltage and configured to open or close based on the second reference signal.

In several embodiments, the low noise amplifier further includes a third stage biased by a third bias signal, the reference signal generator is further configured to generate a third reference signal, and the low noise amplifier bias circuit is further configured to generate the third bias signal based on the third reference signal. According to a number of embodiments, the first stage is an input stage, the second stage is an output stage, and the third stage is an intermediate stage connected between the input stage and the output stage. In accordance with various embodiments, the first stage is an input stage, the third stage is an output stage, and the second stage is an intermediate stage connected between the input stage and the output stage.

In various embodiments, the front-end system includes a capacitor configured to couple a portion of the radio frequency input signal to an input of the power detector.

In several embodiments, the front-end system includes an input splitter having an input configured to receive the radio frequency input signal, a first output that provides a first output signal to an input of the power detector, and a second output that provides a second output signal to the first stage of the low noise amplifier.

In some embodiments, the front-end system further includes a memory element configured to receive the detection signal.

In various embodiments, the front-end system further includes a switch controlled by the detection signal.

In a number of embodiments, the low noise amplifier bias circuit receives the detection signal.

In several embodiments, the front-end system further includes a mode control circuit configured to receive the detection signal.

In various embodiments, the front-end system further includes a flag detector configured to receive the detection signal.

In some embodiments, the front-end system includes a capacitor configured to couple a portion of the radio frequency input signal to an input of the power detector.

In various embodiments, the front-end system includes an input splitter having an input configured to receive the radio frequency input signal, a first output that provides a first output signal to an input of the power detector, and a second output that provides a second output signal to the first stage of the power amplifier.

In several embodiments, the front-end system further includes a memory element configured to receive the detection signal.

In some embodiments, the front-end system further includes a switch controlled by the detection signal.

In various embodiments, the power amplifier bias circuit receives the detection signal.

In several embodiments, the front-end system further includes a mode control circuit configured to receive the detection signal.

In some embodiments, the front-end system further includes a flag detector configured to receive the detection signal.

In certain embodiments, the present disclosure relates to a method of power detection in a low noise amplifier system. The method includes amplifying a radio frequency input signal using a low noise amplifier that includes a first stage biased by a first bias signal and a second stage biased by a second bias signal, generating a first reference signal and a second reference signal using a reference signal generator, generating the first bias signal based on the first reference signal and generating the second bias signal based on the second reference signal using a bias circuit, generating a detection signal based on sensing a power of the radio frequency input signal using a power detector, and selectively enabling the power detector using the second reference signal.

In various embodiments, the method further includes using the bias circuit to disable at least one stage of the low noise amplifier in response to activation of the detection signal to provide ruggedness protection.

In several embodiments, the method further includes the low noise amplifier is operable in a plurality of operating modes, the method further includes processing the detection signal to set an operating mode of the low noise amplifier to a selected operating mode chosen from the plurality of operating modes.

In some embodiments, the first stage is an input stage. According to a number of embodiments, the second stage is an output stage. In accordance with several embodiments, the second stage is an intermediate stage connected between the input stage and an output stage.

In various embodiments, the method further includes using a pull-down transistor to pull-down at least one of the first bias signal or the second bias signal in response to activation of the detection signal.

In several embodiments, the method further includes using the power detector to activate the detection signal in response to the power of the radio frequency input signal exceeding a power threshold. According to a number of embodiments, a value of the power threshold changes with temperature to provide temperature compensation. In accordance with various embodiments, a value of the power threshold changes with a supply voltage of the low noise amplifier to provide supply voltage compensation.

In some embodiments, the reference signal generator includes a first current source configured to generate the first reference signal as a first reference current and a second current source configured to generate the second reference signal as a second reference current.

In various embodiments, the power detector includes a detection circuit configured to receive a portion of the radio frequency input signal and to output the detection signal, and a gating circuit connected between the power detector and a ground voltage and configured to open or close based on the second reference signal.

In several embodiments, the low noise amplifier further includes a third stage biased by a third bias signal, the method further comprising generating a third reference signal using the reference signal generator, and generating the third bias signal based on the third reference signal using the bias circuit.

In various embodiments, the first stage is an input stage, the second stage is an output stage, and the third stage is an intermediate stage connected between the input stage and the output stage.

In some embodiments, the first stage is an input stage, the third stage is an output stage, and the second stage is an intermediate stage connected between the input stage and the output stage.

In several embodiments, the method further includes using a capacitor to couple a portion of the radio frequency input signal to an input of the power detector.

In some embodiments, the method further includes using an input splitter to couple a portion of the radio frequency input signal to an input of the power detector.

In various embodiments, the method further includes receiving the detection signal as an input to a memory element.

In several embodiments, the method further includes controlling a switch based on the detection signal.

In some embodiments, the method further includes receiving the detection signal as an input to the bias circuit.

In various embodiments, the method further includes receiving the detection signal as an input to a mode control circuit.

In several embodiments, the method further includes receiving the detection signal as an input to a flag detector.

In certain embodiments, the present disclosure relates to a low noise amplifier system. The low noise amplifier system includes a low noise amplifier configured to amplify a radio frequency input signal, the low noise amplifier including a first stage biased by a first bias signal and a second stage biased by a second bias signal. The low noise amplifier system further includes a reference signal generator configured to generate a first reference signal and a second reference signal, a bias circuit configured to generate the first bias signal based on the first reference signal and the second bias signal based on the second reference signal, and a power detector that generates a detection signal based on sensing a power of the radio frequency input signal, the power detector selectively enabled by the second reference signal.

In various embodiments, the bias circuit disables at least one stage of the low noise amplifier in response to activation of the detection signal to provide ruggedness protection.

In several embodiments, the low noise amplifier is operable in a plurality of operating modes, and the bias circuit processes the detection signal to set an operating mode of the low noise amplifier to a selected operating mode chosen from the plurality of operating modes.

In some embodiments, the first stage is an input stage. According to a number of embodiments, the second stage is an output stage. In accordance with various embodiments, the second stage is an intermediate stage connected between the input stage and an output stage.

In several embodiments, the bias circuit includes a pull-down transistor configured to pull-down at least one of the first bias signal or the second bias signal in response to activation of the detection signal.

In various embodiments, the power detector activates the detection signal in response to the power of the radio frequency input signal exceeding a power threshold. According to several embodiments, a value of the power threshold changes with temperature to provide temperature compensation. In accordance with a number of embodiments, a value of the power threshold changes with a supply voltage of the low noise amplifier to provide supply voltage compensation.

In several embodiments, the reference signal generator includes a first current source configured to generate the first reference signal as a first reference current and a second current source configured to generate the second reference signal as a second reference current.

In various embodiments, the power detector includes a detection circuit configured to receive a portion of the radio frequency input signal and to output the detection signal, and a gating circuit connected between the power detector and a ground voltage and configured to open or close based on the second reference signal. According to a number of embodiments, the low noise amplifier further includes a third stage biased by a third bias signal, the reference signal generator is further configured to generate a third reference signal, and the bias circuit is further configured to generate the third bias signal based on the third reference signal. In accordance with several embodiments, the first stage is an input stage, the second stage is an output stage, and the third stage is an intermediate stage connected between the input stage and the output stage. According to some embodiments, the first stage is an input stage, the third stage is an output stage, and the second stage is an intermediate stage connected between the input stage and the output stage.

In several embodiments, the low noise amplifier system further includes a capacitor configured to couple a portion of the radio frequency input signal to an input of the power detector.

In various embodiments, the low noise amplifier system further includes an input splitter having an input configured to receive the radio frequency input signal, a first output that provides a first output signal to an input of the power detector, and a second output that provides a second output signal to the first stage of the low noise amplifier.

In some embodiments, the low noise amplifier system further includes a memory element configured to receive the detection signal.

In several embodiments, the low noise amplifier system further includes a switch controlled by the detection signal.

In various embodiments, the bias circuit receives the detection signal.

In some embodiments, the low noise amplifier system further includes a mode control circuit configured to receive the detection signal.

In several embodiments, the low noise amplifier system further includes a flag detector configured to receive the detection signal.

In certain embodiments, the present disclosure relates to a method of power detection in a radio frequency amplifier system. The method includes amplifying a radio frequency input signal using a radio frequency amplifier that includes a first stage biased by a first bias signal and a second stage biased by a second bias signal, generating a first reference signal and a second reference signal using a reference signal generator, generating the first bias signal based on the first reference signal and generating the second bias signal based on the second reference signal using a bias circuit, generating a detection signal based on sensing a power of the radio frequency input signal using a power detector, and selectively enabling the power detector using the second reference signal.

In several embodiments, the method further includes using the bias circuit to disable at least one stage of the radio frequency amplifier in response to activation of the detection signal to provide ruggedness protection.

In some embodiments, the radio frequency amplifier is operable in a plurality of operating modes, and the method further includes processing the detection signal to set an operating mode of the radio frequency amplifier to a selected operating mode chosen from the plurality of operating modes.

In various embodiments, the first stage is an input stage. According to several embodiments, the second stage is an output stage. In accordance with a number of embodiments, the second stage is an intermediate stage connected between the input stage and an output stage.

In some embodiments, the method further includes using a pull-down transistor to pull-down at least one of the first bias signal or the second bias signal in response to activation of the detection signal.

In various embodiments, the method further includes using the power detector to activate the detection signal in response to the power of the radio frequency input signal exceeding a power threshold. According to a number of embodiments, a value of the power threshold changes with temperature to provide temperature compensation. In accordance with several embodiments, a value of the power threshold changes with a supply voltage of the radio frequency amplifier to provide supply voltage compensation.

In some embodiments, the reference signal generator includes a first current source configured to generate the first reference signal as a first reference current and a second current source configured to generate the second reference signal as a second reference current.

In various embodiments, the power detector includes a detection circuit configured to receive a portion of the radio frequency input signal and to output the detection signal, and a gating circuit connected between the power detector and a ground voltage and configured to open or close based on the second reference signal.

In various embodiments, the radio frequency amplifier further includes a third stage biased by a third bias signal, and the method further includes generating a third reference signal using the reference signal generator, and generating the third bias signal based on the third reference signal using the bias circuit. According to a number of embodiments, the first stage is an input stage, the second stage is an output stage, and the third stage is an intermediate stage connected between the input stage and the output stage. In accordance with several embodiments, the first stage is an input stage, the third stage is an output stage, and the second stage is an intermediate stage connected between the input stage and the output stage.

In some embodiments, the method further includes using a capacitor to couple a portion of the radio frequency input signal to an input of the power detector.

In several embodiments, the method further includes using an input splitter to couple a portion of the radio frequency input signal to an input of the power detector.

In various embodiments, the method further includes receiving the detection signal as an input to a memory element.

In some embodiments, the method further includes controlling a switch based on the detection signal.

In several embodiments, the method further includes receiving the detection signal as an input to the bias circuit.

In some embodiments, the method further includes receiving the detection signal as an input to a mode control circuit.

In various embodiments, the method further includes receiving the detection signal as an input to a flag detector.

In several embodiments, the radio frequency amplifier is a power amplifier.

In some embodiments, the radio frequency amplifier is a low noise amplifier.

In certain embodiments, the present disclosure relates to a radio frequency amplifier system. The radio frequency amplifier system includes a radio frequency amplifier configured to amplify a radio frequency input signal, the radio frequency amplifier including a first stage biased by a first bias signal and a second stage biased by a second bias signal. The radio frequency amplifier system further includes a reference signal generator configured to generate a first reference signal and a second reference signal, a bias circuit configured to generate the first bias signal based on the first reference signal and the second bias signal based on the second reference signal, and a power detector that generates a detection signal based on sensing a power of the radio frequency input signal, the power detector selectively enabled by the second reference signal.

In various embodiments, the bias circuit disables at least one stage of the radio frequency amplifier in response to activation of the detection signal to provide ruggedness protection.

In several embodiments, the radio frequency amplifier is operable in a plurality of operating modes, and the bias circuit processes the detection signal to set an operating mode of the radio frequency amplifier to a selected operating mode chosen from the plurality of operating modes.

In some embodiments, the first stage is an input stage. According to a number of embodiments, the second stage is an output stage. In accordance with several embodiments, the second stage is an intermediate stage connected between the input stage and an output stage.

In various embodiments, the bias circuit includes a pull-down transistor configured to pull-down at least one of the first bias signal or the second bias signal in response to activation of the detection signal.

In several embodiments, the power detector activates the detection signal in response to the power of the radio frequency input signal exceeding a power threshold. According to a number of embodiments, a value of the power threshold changes with temperature to provide temperature compensation. In accordance with various embodiments, a value of the power threshold changes with a supply voltage of the radio frequency amplifier to provide supply voltage compensation.

In some embodiments, the reference signal generator includes a first current source configured to generate the first reference signal as a first reference current and a second current source configured to generate the second reference signal as a second reference current.

In various embodiments, the power detector includes a detection circuit configured to receive a portion of the radio frequency input signal and to output the detection signal, and a gating circuit connected between the power detector and a ground voltage and configured to open or close based on the second reference signal.

In several embodiments, the radio frequency amplifier further includes a third stage biased by a third bias signal, the reference signal generator is further configured to generate a third reference signal, and the bias circuit is further configured to generate the third bias signal based on the third reference signal. According to a number of embodiments, the first stage is an input stage, the second stage is an output stage, and the third stage is an intermediate stage connected between the input stage and the output stage. In accordance with several embodiments, the first stage is an input stage, the third stage is an output stage, and the second stage is an intermediate stage connected between the input stage and the output stage.

### BRIEF DESCRIPTION OF THE DRAWINGS

FIG. 1 is a schematic diagram of an RF amplifier system with ruggedness protection according to one embodiment.

FIG. 2A is a schematic diagram of an RF amplifier system with ruggedness protection according to another embodiment.

FIG. 2B is a schematic diagram of a power detector according to one embodiment.

FIG. 2C is one example of a graph of detector output voltage versus RF power for a power detector.

FIG. 2D is another example of a graph of detector output voltage versus RF power for a power detector.

FIG. 2E is another example of a graph of detector output voltage versus RF power for a power detector.

FIG. 3 is a schematic diagram of an RF amplifier system with ruggedness protection according to another embodiment.

FIG. 4A is a schematic diagram of an RF amplifier system with ruggedness protection according to another embodiment.

FIG. 4B is a schematic diagram of a multi-mode RF amplifier system according to one embodiment.

FIG. 5A is a schematic diagram of one embodiment of a circuit for RF input signal sensing.

FIG. 5B is a schematic diagram of another embodiment of a circuit for RF input signal sensing.

FIG. 6A is a schematic diagram of one embodiment of a circuit for processing a power detector output signal.

FIG. 6B is a schematic diagram of another embodiment of a circuit for processing a power detector output signal.

FIG. 6C is a schematic diagram of another embodiment of a circuit for processing a power detector output signal.

FIG. 7A is a schematic diagram of one embodiment of a circuit for controlling RF amplifier bias based on a power detector output signal.

FIG. 7B is a schematic diagram of one embodiment of a circuit for controlling RF amplifier mode based on a power detector output signal.

FIG. 7C is a schematic diagram of one embodiment of a circuit for flag detection based on a power detector output signal.

FIG. 8 is a schematic diagram of one embodiment of a mobile device.

FIG. 9A is a schematic diagram of another embodiment of a mobile device.

FIG. 9B is a schematic diagram of another embodiment of a mobile device.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Radio frequency (RF) amplifiers are subject to ruggedness failures. For example, power amplifiers often suffer from ruggedness failures resulting from a combination of high input power and a high voltage standing wave ratio (VSWR) condition presented on an output load. The resulting high voltage and current peaks lead to transistor damage and/or other electrical damage that renders the power amplifier part inoperable. Inadequate ruggedness of a power amplifier can result in failures after deployment of the power amplifier in a final application as well as during board bring up on a customer side.

Existing techniques for addressing ruggedness failures suffer from several drawbacks. In a first example, one or more diode stacks are placed at an output of a power amplifier to rectify voltage waves. Although such an approach can provide some ruggedness protection, the diode stacks tend to have a turn-on voltage (VT) shift over temperature that results in the diode stacks providing insufficient limiting at cold temperatures. Although the number of diodes in each stack can be reduced to turn the stacks on at lower voltage, this may result in the diode stacks turning on under a non-VSWR condition at hot temperatures.

In a second example, a power amplifier's output is sensed to provide feedback that shuts down the power amplifier at high signaling levels. Although such an approach can provide limiting under certain operating scenarios, feeding back a signal from power amplifier output to bias can cause instability, degradation of high peak-to-average-power ratio (PAPR) signal waveforms, and/or be too slow to turn off the power amplifier before damage occurs.

In a third example, up/down diodes are placed at an input of a power amplifier to provide rectification to achieve some ruggedness protection. However, such a configuration may provide insufficient rectification due to the VT of the diode being too low to trigger for the small signal swing typically present at the power amplifier's input. Furthermore, the diodes can add capacitance at the power amplifier's input and thereby cause input matching problems and/or degradation of high PAPR signals.

Apparatus and methods for RF amplifier ruggedness protection are disclosed. In certain embodiments, an RF amplifier system includes an RF amplifier, a bias circuit that biases the RF amplifier with two or more bias signals, and a reference signal generator that generates two or more reference signals for the bias circuit. The bias circuit uses a first reference signal of the reference signals to bias an input stage of the RF amplifier and a second reference signal to bias another stage of the RF amplifier (for instance, an output stage or an intermediate stage between the input stage and the output stage). The RF amplifier system further includes a power detector that generates a detection signal based on sensing an RF input signal to the input stage. The power detector is selectively enabled (turned on or off) using the second reference signal.

By implementing the RF amplifier system in this manner, input power detection can be used to trigger a shutdown of the RF amplifier's bias in order to reduce or eliminate ruggedness failures. Furthermore, by turning on or off the power detector using the second reference signal, a feature is provided to power-gate the power detector to eliminate off-state leakage current while saving on module cost. For example, such a technique can provide lower cost relative to a configuration in which another die is added to provide a regulated control voltage to turn on or off the power detector. In contrast, the second reference signal is already used by the bias circuit, and thus can be used both for biasing the RF amplifier and to gate the turn on of the power detector to achieve reduced leakage.

Thus, the power detector does not need an additional enable signal to be disabled in a non-transmit state (for instance, receive, bypass, off, etc.) to eliminate leakage current. Rather, an existing reference signal to the bias circuit can be reused.

In certain implementations, the detection signal from the power detector is used to shut down the RF amplifier's bias. In a first example, the detection signal triggers a pull-down transistor that reduces the bias current to one or more stages of the RF amplifier. In a second example, the detection signal is used to trigger a shut-down circuit in a silicon implementation of the bias (i.e. flipping a logic state).

The teachings herein allow input power detection to be easier to implement in an RF amplifier relative to a configuration using output sensing techniques. For example, using input power detection provides less disruption to the RF signal chain in terms of matching and no long feedback connections are needed from the output of the RF amplifier to input.

The power detector is also relatively small and easily integrated into the RF amplifier with minimal cost and/or disruption to the rest of the RF amplifier's design. Furthermore, the power detector can be adjusted for any output voltage to drive a variety of shut down techniques depending on an implementation of the RF amplifier bias. Furthermore, the detector can be adjusted to be temperature compensated to trigger at different power thresholds, which can be selected depending on the RF amplifier's characteristics.

The power detection schemes herein can be used for a wide variety of RF amplifiers, including, for example, power amplifiers and/or low noise amplifiers (LNAs).

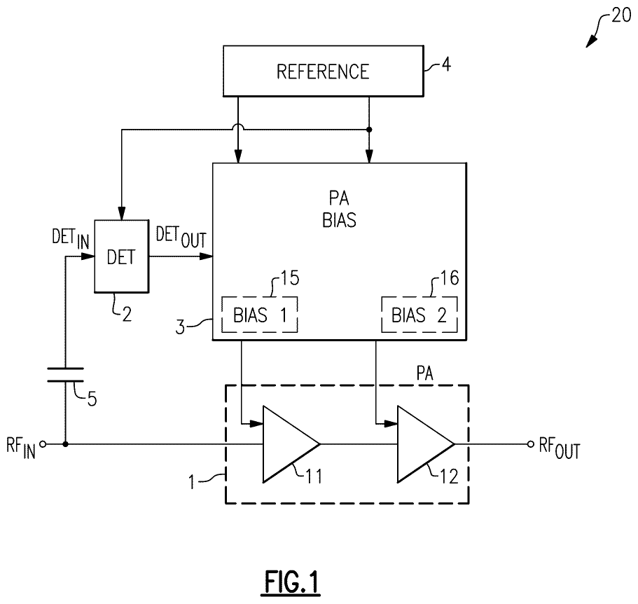

FIG. 1 is a schematic diagram of an RF amplifier system 20 with ruggedness protection according to one embodiment. The RF amplifier system 20 includes an RF amplifier (a power amplifier 1, in this embodiment), a power detector 2, a bias circuit (a power amplifier bias circuit 3, in this embodiment), a reference signal generator 4, and an input capacitor 5.

Although shown for an example of a power amplifier, the teachings herein are applicable to other types of RF amplifiers, such as LNAs.

As shown in FIG. 1, the RF amplifier system 20 includes an RF input RF_{IN} for receiving an RF input signal and an RF output RF_{OUT} for providing an RF output signal. Additionally, the power amplifier 1 includes a first power amplifier stage 11 in cascade with a second power amplifier stage 12. The first power amplifier stage 11 amplifies the RF input signal to generate an RF amplified signal, which the second power amplifier stage 12 further amplifies to generate the RF output signal.

Although an example with two power amplifier stages is shown, the teachings herein are also applicable to RF amplifier systems using more or fewer stages.

With continuing reference to FIG. 1, the reference generator 4 outputs a first reference signal and a second reference signal. In certain implementations, the reference generator 4 is formed on a separate die from other components of the RF amplifier system 20. In one example, the power amplifier 1, the power detector 2, and the power amplifier bias circuit 3 are formed on a first semiconductor die, while the reference signal generator 4 is formed on a second semiconductor die. In such implementations, the dies can be of different processing technologies. For instance, the first semiconductor die can be a gallium arsenide (GaAs) die or a silicon germanium (SiGe) die while the second semiconductor die can be a silicon (Si) die.

As shown in FIG. 1, the power amplifier bias circuit 3 receives the first reference signal and the second reference signal from the reference signal generator 4. Additionally, the power amplifier bias circuit 3 includes a first stage bias circuit 15 that generates a first bias signal for the first power amplifier stage 11 based on the first reference signal, and a second stage bias circuit 16 that generates a second bias signal for the second power amplifier stage 12.

The input capacitor 5 couples in the RF input signal to thereby sense RF signal power and generate a detector input signal DET_{IN} for the power detector 2. The input capacitor 5 also serves as a DC blocking capacitor to decouple the DC input bias voltage of the power detector 2 and the power amplifier 1 (for instance, a bias voltage for a base of a bipolar transistor at the input of stage 11). The power detector 2 processes the detector input signal DET_{IN} to generate a detector output signal DET_{OUT} (also referred to herein as a detection signal) that is provided to the power amplifier bias circuit 3. In certain implementations, the power detector 2 generates the detector output signal DET_{OUT} based on comparing the detector input signal DET_{IN} to a threshold. For example, the detector output signal DET_{OUT} can be activated in response to the signal power of the RF input signal exceeding a power threshold.

As shown in FIG. 1, the second reference signal is also provided to the power detector 2 to selectively enable the power detector 2. By turning on or off the power detector 2 using the reference signal, a feature is provided to power-gate the power detector 2 to eliminate off-state leakage current while saving on module cost.

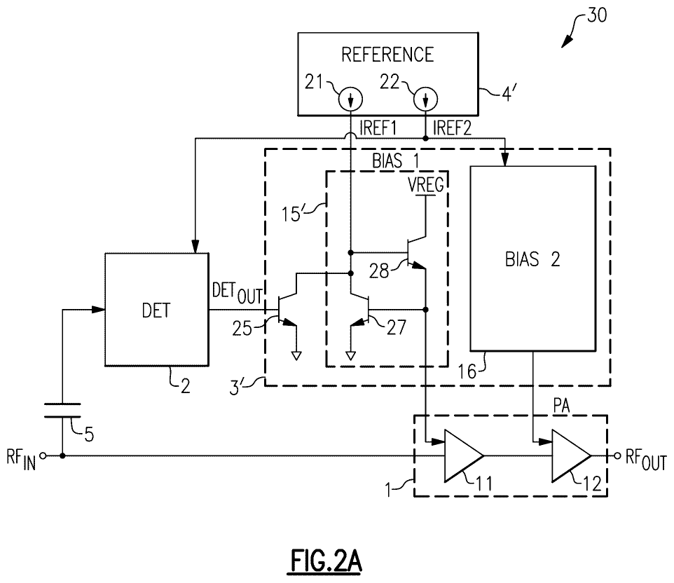

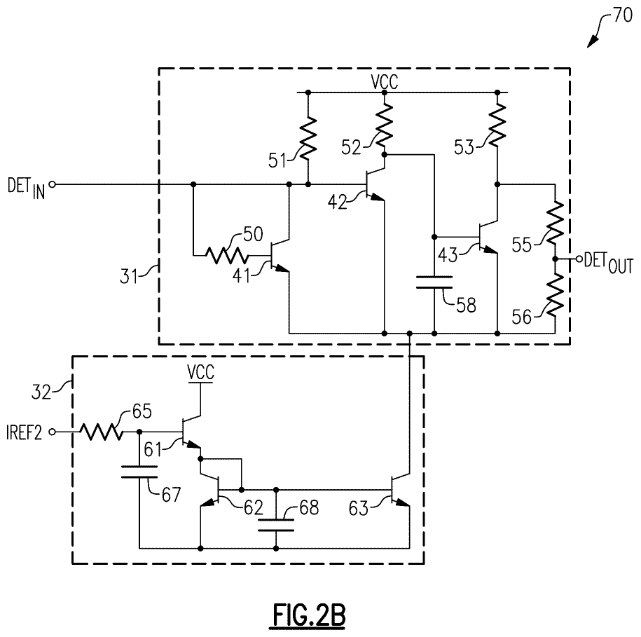

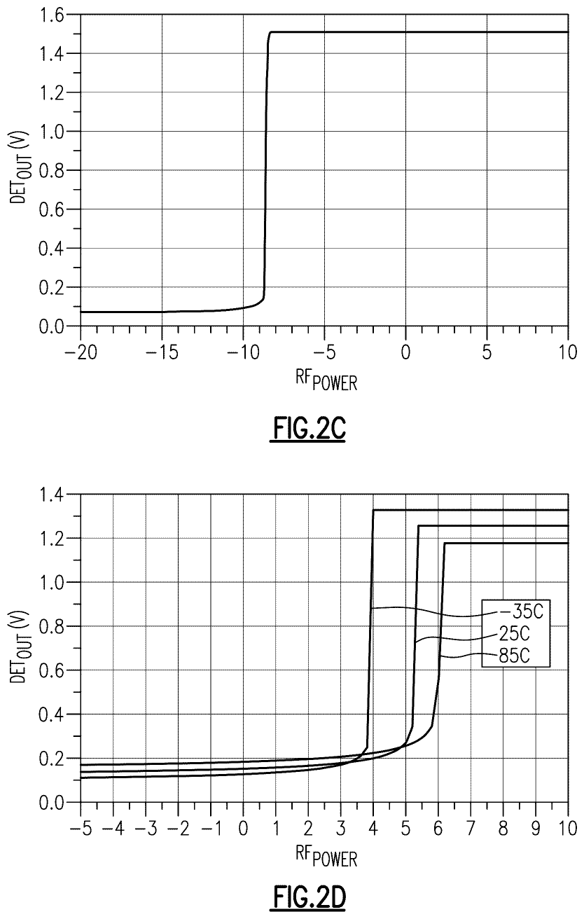

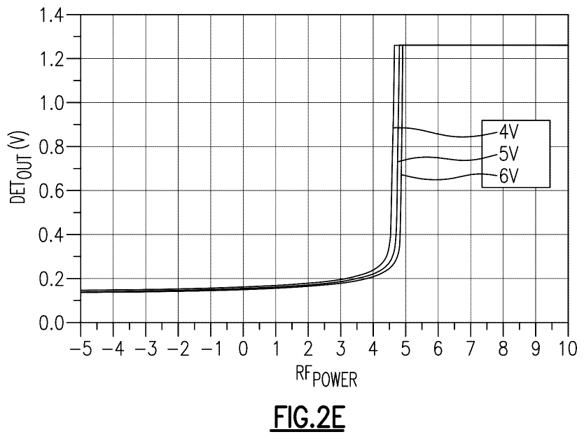

FIG. 2A is a schematic diagram of an RF amplifier system 30 with ruggedness protection according to another embodiment. The RF amplifier system 30 includes a power amplifier 1, a power detector 2, a power amplifier bias circuit 3′, a reference current generator 4′, and an input capacitor 5.

The RF amplifier system 30 of FIG. 2A is similar to the RF amplifier system 20 of FIG. 1, except that the RF amplifier system 30 of FIG. 2A illustrates a specific implementation of reference signal generation and power amplifier biasing.

As shown in FIG. 2A, the reference current generator 4′ includes a first current source 21 that generates a first reference current IREF1 and a second current source 22 that generates a second reference current IREF2. Additionally, the power amplifier bias circuit 3′ includes a first stage bias circuit 15′ that generates a first bias signal for the first power amplifier stage 11 based on the first reference current IREF1, and a second stage bias circuit 16 that generates a second bias signal for the second power amplifier stage 12 based on the second reference current IREF2. The second reference current IREF2 is also provided to the power detector 2 to turn on or off the power detector 2. The power amplifier bias circuit 3′ also includes a shutoff bipolar transistor 25 that disables the first stage bias circuit 15′ in response to activation of the detector output signal DET_{OUT} by the power detector 2.

In the illustrated embodiment, the first stage bias circuit 15′ includes a first bipolar bias transistor 27 and a second bipolar bias transistor 28. The emitter of the first bipolar bias transistor 27 is connected to a ground voltage while a collector of the first bipolar bias transistor 27 is connected to a base of the second bipolar bias transistor 28 at a node that receives the first reference current IREF1. Additionally, the collector of the second bipolar bias transistor 28 is connected to a regulated voltage while an emitter of the second bipolar bias transistor 28 is connected to a base of the first bipolar bias transistor 27 at a node that generates the first bias signal. Additionally, the shutoff bipolar transistor 25 includes a base that receives the detector output signal DET_{OUT}, an emitter connected to the ground voltage, and a collector that is connected to the collector of the first bipolar bias transistor 27.

Thus, the RF amplifier system 30 operates by coupling input signal power from the RF input RF_{IN} through the input capacitor 5 to the power detector 2. Additionally, the power detector 2 has a voltage output that is pulled high when triggered and that otherwise stays low. When the power detector 2 is fully triggered the detector output signal DET_{OUT} turns on the shutoff bipolar transistor 25 to sink the first reference current IREF1 to ground and reducing the current that would have otherwise been used to generate the bias of the first power amplifier stage 11.

By turning off or reducing the bias current to the first stage 11, there is less power gain, and hence less power through the power amplifier 1. This in turn protects the power amplifier 1 from being damaged as well as other subsequent stages further down the RF chain by limiting the output power from stage 1.

FIG. 2B is a schematic diagram of a power detector 70 according to one embodiment. The power detector 70 includes a detection circuit 31 and a gating circuit 32. The detection circuit 31 includes an input node that receives a detector input signal DET_{IN} and an output node that provides a detector output signal DET_{OUT}. Additionally, the detection circuit 31 receives power from a power supply voltage VCC (which in certain implementations is a power supply voltage also used for a power amplifier) and is connected to a ground voltage through the gating circuit 32. The gating circuit 32 receives a reference signal (corresponding to the second reference current IREF2, in this example), which the gating circuit 32 uses to selectively enable (turn on or off) the detection circuit 32 by controlling the connection of the detection circuit 31 to the ground voltage. Accordingly, the gating circuit 32 provides low side gating, in this example.

In the illustrated embodiment, the detection circuit 31 includes a first detection bipolar transistor 41, a second detection bipolar transistor 42, a third detection bipolar transistor 43, an input resistor 50, a first biasing resistor 51, a second biasing resistor 52, a third biasing resistor 53, a first output resistor 55, a second output resistor 56, and a capacitor 58.

The input resistor 50 includes a first end that is connected to the input node a second end that is connected to a base of the first detection bipolar transistor 41. Additionally, the collector of the first detection bipolar transistor 41 is connected to the input node and an emitter of the first detection bipolar transistor 41 is connected to a gating node that is controlled by the gating circuit 32. The first biasing resistor 51 includes a first end connected to the input node and a second end connected to the power supply voltage VCC.

With continuing reference to FIG. 2B, the second detection bipolar transistor 42 includes a base connected to the input node, an emitter connected to the gating node, and a collector connected to a base of the third detection bipolar transistor 43. The second biasing resistor 52 includes a first end connected to the base of the third detection bipolar transistor 43 and a second end connected to the power supply voltage VCC. The capacitor 58 includes a first end connected to the base of the third detection bipolar transistor 43 and a second end connected to the gating node. The third detection bipolar transistor 43 further includes an emitter connected to the gating node and a collector connected to a first end of the third biasing resistor 53 and to a first end of the first output resistor 55. The third biasing resistor 53 further includes a second end connected to the power supply voltage VCC, while the first output resistor 55 further includes a second end connected to the output node. The second output resistor 56 includes a first end connected to the output node and a second end connected to the gating node.

In the illustrated embodiment, the gating circuit 32 includes a first gating control bipolar transistor 61, a second gating control bipolar transistor 62, a third gating control bipolar transistor 63, a resistor 65, a first capacitor 67, and a second capacitor 68. The resistor 65 includes a first end that receives the reference signal (corresponding to a portion of the second reference current IREF2, in this example), and a second end connected to the base of the first gating control bipolar transistor 61. The first capacitor 67 includes a first end connected to the base of the first gating control bipolar transistor 61 and a second end connected to the ground voltage. Additionally, the first gating control bipolar transistor 61 includes a collector connected to the power supply voltage VCC and an emitter connected to a collector and a base of the second gating control bipolar transistor 62, to a first end of the second capacitor 68, and to a base of the third gating control bipolar transistor 63. An emitter of the second gating control bipolar transistor 62, a second end of the second capacitor 68, and an emitter of the third gating control bipolar transistor 63 are connected to the ground voltage. The third gating control bipolar transistor 63 further includes a collector connected to the gating node.

Signal power is fed to the power detector 70 by way of the detector input DET_{IN}, which is generated based on sensing an RF input signal of a power amplifier. The first detection bipolar transistor 41 is diode-connected and serves as the primary detection element. For example, the first detection bipolar transistor 41 serves to convert a received RF input signal to a corresponding DC voltage level at the collector of the second detection bipolar transistor 42. The DC voltage level is then inverted and shifted via the networks around the second detection bipolar transistor 42 and the third detection bipolar transistor 43. The output voltage of the detector 70 is set by the voltage divider formed by the third biasing resistor 43, the first output resistor 55, and the second output resistor 56.

With continuing reference to FIG. 2B, the capacitor 58 serves to filter the RF signal components in the output of the power detector 70 such that the detector output signal DET_{OUT} is mostly DC. The sensitivity of the power detector 70 is controlled by the size and bias of the first detection bipolar transistor 41, which is set by the input resistor 50 and the first biasing resistor 51. These three elements can also be implemented to control a temperature characteristic of the power detector 70.

In certain implementations, the power detector 70 is fabricated in GaAs, and implanted resistors are used to form the resistors shown in FIG. 2B. Implanted resistors in a GaAs process have a temperature characteristic that can be employed to provide built-in temperature compensation to the power detector 70. For example, at low temperature, resistance is reduced through the first biasing resistor 51 and hence a higher bias is set at the input node making the first detection bipolar transistor 41 easier to turn on. Additionally, the transistors themselves have a lower turn on voltage at cold.

The gating circuit 32 turns off the detection circuit in OFF mode by the third latching control transistor 63, which serves as a low side switch. The third latching control transistor 63 is biased by a signal generated based on the resistor 65, the first latching control bipolar transistor 61, and the second latching control bipolar transistor 62 sensing an internal voltage at the reference input that receives the second reference current IREF2.

FIG. 2C is one example of a graph of detector output voltage versus RF power for a power detector.

The graph demonstrates one example response for one implementation of the power detector 70 of FIG. 2B. As shown in FIG. 2C, there is a sharp rise in detector output voltage at a specific input power, in this case −9 dBm.

The output voltage of the power detector 70 can be adjusted by circuit implementation to achieve desired characteristics depending on the specific type of circuit receiving the detector output signal. For instance, in an application with a pulldown bipolar transistor with a threshold voltage of 1.3V, a detector output voltage of 1.5 V can be selected. However, the output voltage could be lower or higher depending on the technology and/or type of receiving circuit.

FIG. 2D is another example of a graph of detector output voltage versus RF power for a power detector. The graph demonstrates another example response of the power detector 70 of FIG. 2B for temperatures of −35° C., +25° C., and +85° C.

A power detector can also be designed to have a temperature characteristic to the power threshold. For instance, for a GaAs power amplifier, there is more RF gain at cold temperatures over hot due to the properties of the semiconductor. Due to higher gain at cold, it is desirable for the power detector to shut down the power amplifier at a lower input power to protect it.

The depicted graph shows an example of a power detector response over temperature. Note the −35° C. temperature response is turning on at a lower input power than that of +25° C. and +85° C., which is what is desired for this application.

FIG. 2E is another example of a graph of detector output voltage versus RF power for a power detector. The graph demonstrates another example response of the power detector 70 of FIG. 2B for power supply voltages of 4V, 5V, and 6V.

A power detector can also be designed to have a supply voltage characteristic to the power threshold. For instance, for a GaAs power amplifier, a lower power threshold is desired for low supply voltage, while a higher power threshold is desired for high temperature.

FIG. 3 is a schematic diagram of an RF amplifier system 110 with ruggedness protection according to another embodiment. The RF amplifier system 110 includes a power amplifier 101, a power detector 2, a power amplifier bias circuit 103, a reference signal generator 104, and an input capacitor 5.

The RF amplifier system 110 of FIG. 3 is similar to the RF amplifier system 20 of FIG. 1, except that the RF amplifier system 110 includes three stages and corresponding biasing and reference signaling.

For example, as shown in FIG. 3, the power amplifier 101 includes a first power amplifier stage 11, a second power amplifier bias stage 12, and a third power amplifier bias stage 13 in cascade. Additionally, the reference signal generator 104 generates a first reference signal, a second reference signal, and a third reference signal. Furthermore, the power amplifier bias circuit 103 includes a first stage bias circuit 15 that generates a first bias signal for the first power amplifier stage 11 based on the first reference signal, a second stage bias circuit 16 that generates a second bias signal for the second power amplifier stage 12, and a third stage bias circuit 17 that generates a third bias signal for the third power amplifier stage 13.

Although an example with three power amplifier stages is shown, the teachings herein are also applicable to RF amplifier systems using more or fewer stages.

In the illustrated embodiment, the second reference signal is also provided to the power detector 2 to selectively enable the power detector 2. By turning on or off the power detector 2 using the reference signal, a feature is provided to power-gate the power detector 2 to eliminate off-state leakage current while saving on module cost.

Although FIG. 3 depicts an example in which power detector 2 receives the reference signal used for biasing the intermediate stage 12 of the power amplifier 101, other implementations are possible. For example, in another embodiment, the third reference signal (corresponding to that used to bias the output stage 13 of the power amplifier 101) is provided to the power detector 2.

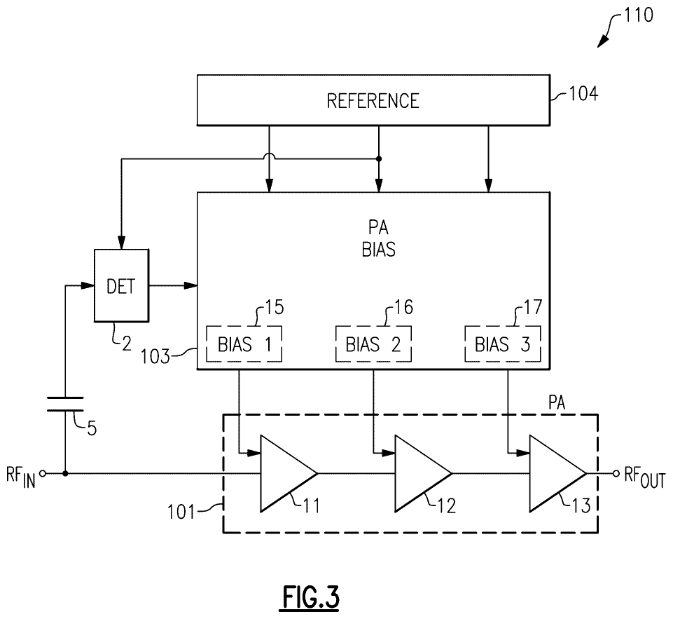

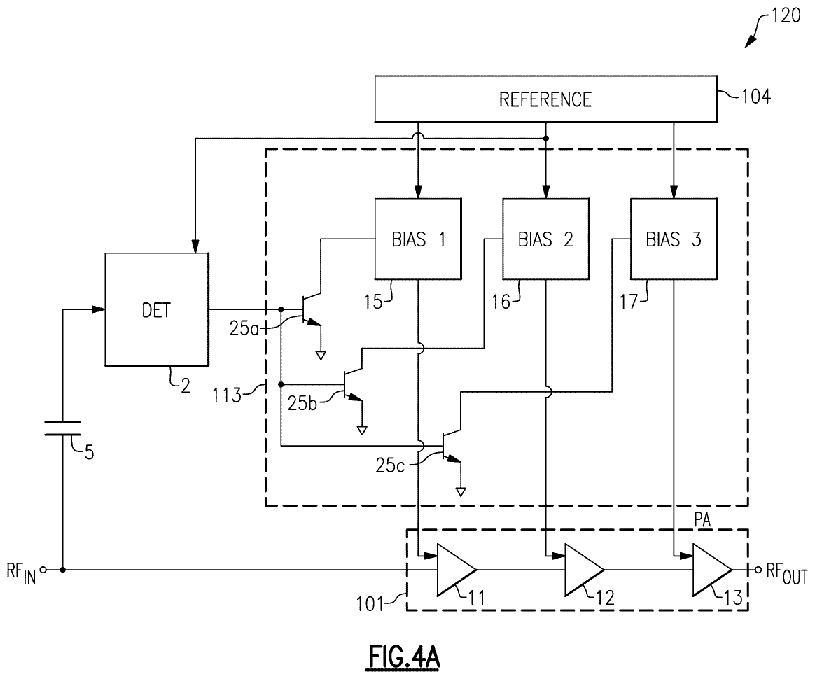

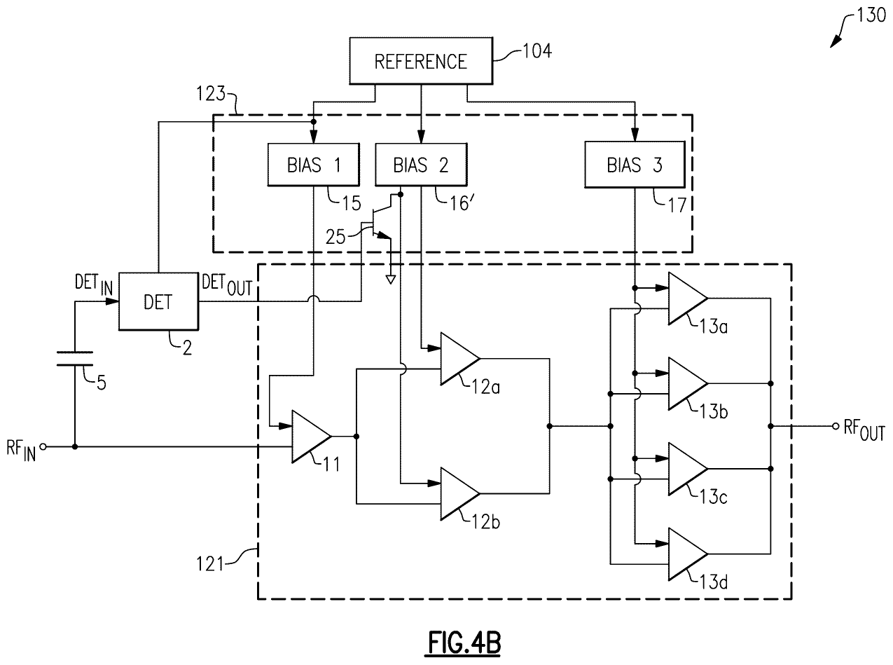

FIG. 4A is a schematic diagram of an RF amplifier system 120 with ruggedness protection according to another embodiment. The RF amplifier system 120 includes a power amplifier 101, a power detector 2, a power amplifier bias circuit 113, a reference signal generator 104, and an input capacitor 5.

The RF amplifier system 120 of FIG. 4A is similar to the RF amplifier system 110 of FIG. 3, except that the RF amplifier system 120 depicts a specific implementation of shutdown in the power amplifier bias circuit 113.

For example, as shown in FIG. 4A, the power amplifier bias circuit 113 includes a first pull-down bipolar transistor 25a, a second pull-down bipolar transistor 25b, a third pull-down bipolar transistor 25c, a first stage bias circuit 15, a second stage bias circuit 16, and a third stage bias circuit 17. Additionally, the detection signal from the power detector 2 is provided to the base of each of the pull-down bipolar transistors 25a-25c. Additionally, the emitters of each of the pull-down bipolar transistors 25a-25c are grounded, while the collectors of the pull-down bipolar transistors 25a-25c are used to deactivate the bias from the bias circuits 15-17, respectively, in response to activation of the detection signal.

By disabling more than one power amplifier stage in response to detecting high input signal power, more robust protection against ruggedness failures is achieved.

FIG. 4B is a schematic diagram of a multi-mode RF amplifier system 130 according to one embodiment. The multi-mode RF amplifier system 130 includes a power amplifier 121, a power detector 2, a power amplifier bias circuit 123, a reference signal generator 104, and an input capacitor 5.

In the illustrated embodiment, the power amplifier 121 includes an input stage 11, an intermediate stage partitioned into a first stage portion 12a and a second stage portion 12b, and an output stage portioned into a first stage portion 13a, a second stage portion 13b, a third stage portion 13c, and a fourth stage portion 13d. Additionally, the power amplifier bias circuit 123 includes a first stage bias circuit 15 that generates a first bias signal for the input stage 11 based on the first reference signal, a second stage bias circuit 16′ that generates second bias signals for each portion 12a-12b of the intermediate stage, and a third stage bias circuit 17 that generates third bias signals for each portion 13a-13d of the output stage. The power amplifier bias circuit 123 also includes a pull-down transistor 25 that turns off the second portion 12b of the intermediate stage in response to the power detector 2 indicating that the RF input signal power exceeds a power threshold.

The multi-mode RF amplifier system 130 is operable in multiple modes, including a first mode in which all portions of the intermediate stage are activated and a second mode in which only the portion 12a of the intermediate stage is activated. The selection of the mode is controlled by the detection signal generated by the power detector 2.

Although one example of a multi-mode power amplifier is depicted, the teachings herein are applicable to using a detector output to choose any type of mode selection of a power amplifier. For example, other portions of power amplifier stage(s) can be activated or deactivated based on the detection signal from the power detector 2. For instance, in another embodiment, one or more portions of an output stage are turned on or off based on the detection signal.

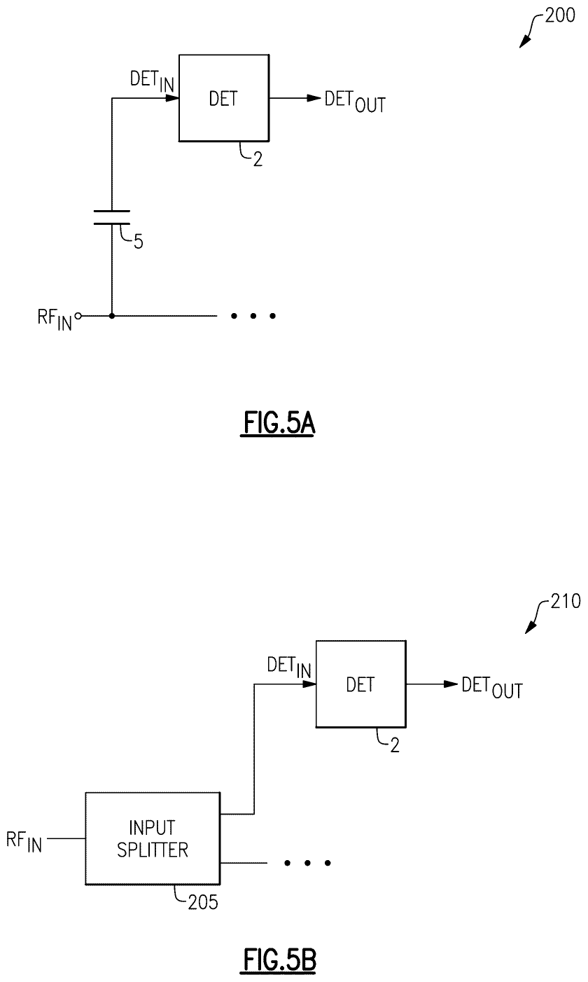

FIG. 5A is a schematic diagram of one embodiment of a circuit 200 for RF input signal sensing. The circuit 200 includes a power detector 2 and a capacitor 5. The capacitor 5 is coupled between an RF input RF_{IN} and an input to the power detector 2 to sense the RF input signal of an RF amplifier (not shown in FIG. 5A).

Any of the embodiments herein can use a capacitor to couple a portion of an RF input signal to an input of a power detector.

FIG. 5B is a schematic diagram of another embodiment of a circuit 210 for RF input signal sensing. The circuit 210 includes a power detector 2 and an input splitter 205. The input splitter 205 includes an input that receives an RF input signal from an RF input RF_{IN}, a first output coupled to an input of the power detector 2, and a second output for coupling to an input of an RF amplifier (not shown in FIG. 5B).

Any of the embodiments herein can use an input splitter to couple a portion of an RF input signal to an input of a power detector. Indeed, a capacitor, an input splitter, or any other suitable circuit can be used to couple a portion of an RF input signal to an input of a power detector.

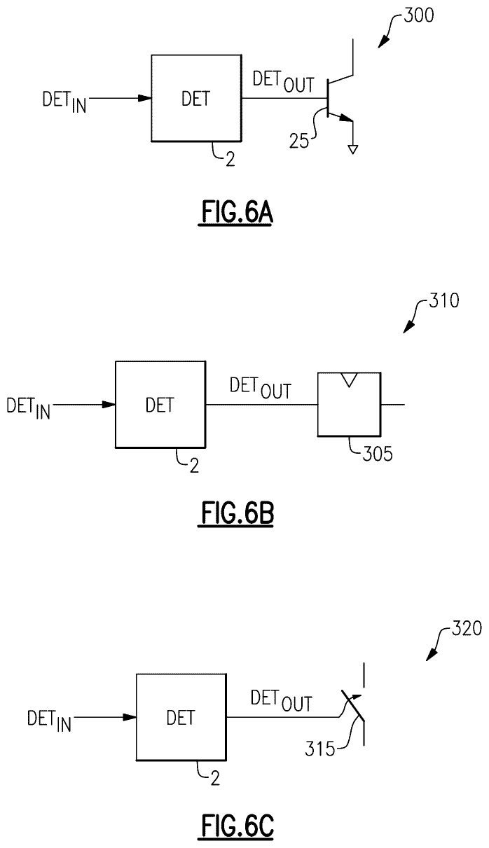

FIG. 6A is a schematic diagram of one embodiment of a circuit 300 for processing a power detector output signal. The circuit 300 includes a power detector 2 and a pull-down bipolar transistor 25. The detector output signal DET_{OUT} from the power detector 2 is provided to a base of the pull-down bipolar transistor 25, in this example.

Any of the embodiments herein can include a pull-down bipolar transistor having a base that receives the detector output signal DET_{OUT}.

FIG. 6B is a schematic diagram of another embodiment of a circuit 310 for processing a power detector output signal. The circuit 310 includes a power detector 2 and a memory element 305, such as a latch or flip-flop. The detector output signal DET_{OUT} from the power detector 2 is provided to the input of the memory element 305, in this example.

Any of the embodiments herein can include a memory element that receives the detector output signal DET_{OUT}. For example, such an implementation can be useful for implementations in which combinatorial logic is used to generate a power amplifier control signal (for example, a shutdown control signal) based on a state of the power detector's output.

FIG. 6C is a schematic diagram of another embodiment of a circuit 320 for processing a power detector output signal. The circuit 320 includes a power detector 2 and a switch 315. The detector output signal DET_{OUT} from the power detector 2 is provided to a control input of the switch 315, in this example.

Any of the embodiments herein can include a switch that is opened or closed based on the detector output signal DET_{OUT}.

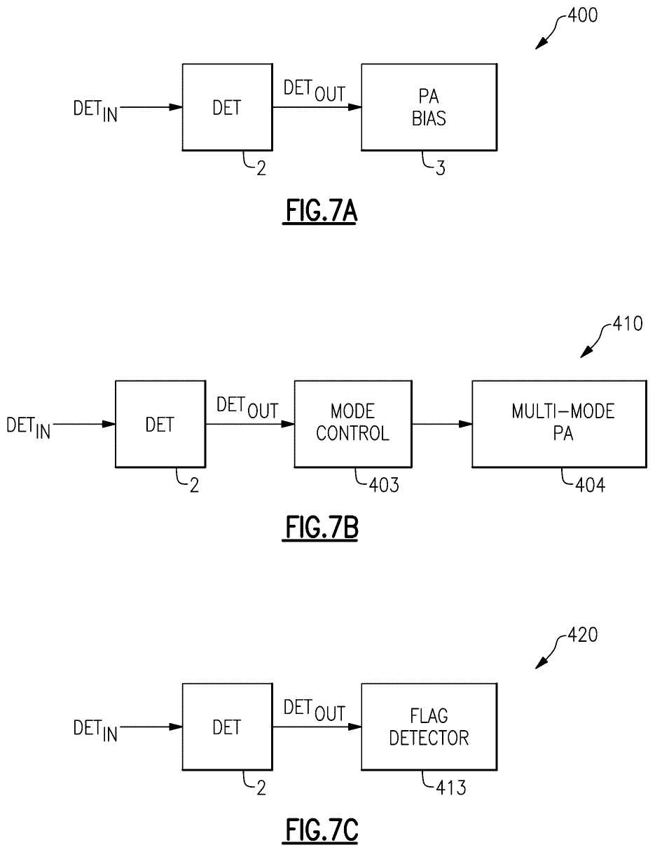

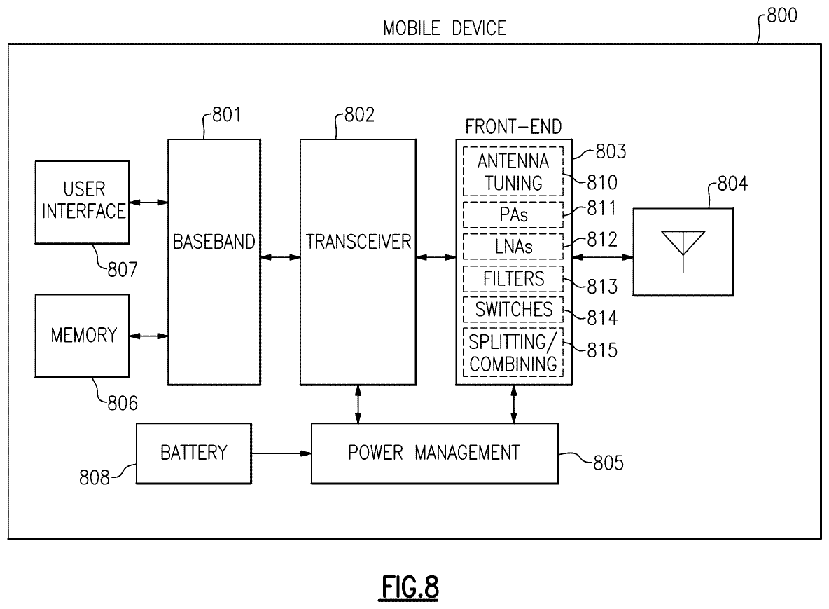

FIG. 7A is a schematic diagram of one embodiment of a circuit 400 for controlling power amplifier bias based on a power detector output signal. The circuit 400 includes a power detector 2 and a power amplifier bias circuit 3 that is controlled based on the detector output signal DET_{OUT} from the power detector 2.

Any of the embodiments herein can include a power amplifier bias circuit 3 controlled by the detector output signal DET_{OUT}.

FIG. 7B is a schematic diagram of one embodiment of a circuit 410 for controlling power amplifier mode based on a power detector output signal. The circuit 410 includes a power detector 2 and a mode control circuit 403 that is controlled based on the detector output signal DET_{OUT} from the power detector 2. The mode control circuit 403 sets an operating mode of a multi-mode power amplifier 404 to a chosen operating mode selected from two or more operating modes.

Any of the embodiments herein can include a mode control circuit 403 controlled by the detector output signal DET_{OUT}.

FIG. 7C is a schematic diagram of one embodiment of a circuit 420 for flag detection based on a power detector output signal. The circuit 420 includes a power detector 2 and a flag detector 413 that is controlled based on the detector output signal DET_{OUT} from the power detector 2. The flag detector 413 can activate one or more flags (for instance, power amplifier status flags) based on the detector output signal DET_{OUT}.

Any of the embodiments herein can include a flag detector 413 controlled by the detector output signal DET_{OUT}.

FIG. 8 is a schematic diagram of one embodiment of a mobile device 800. The mobile device 800 includes a baseband system 801, a transceiver 802, a front-end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 8 as the transceiver 802. In one example, separate components (for instance, separate circuits or dies) can be provided for handling certain types of RF signals.

The front-end system 803 aids in conditioning signals transmitted to and/or received from the antennas 804. In the illustrated embodiment, the front-end system 803 includes antenna tuning circuitry 810, power amplifiers (PAS) 811, low noise amplifiers (LNAs) 812, filters 813, switches 814, and signal splitting/combining circuitry 815. However, other implementations are possible.

For example, the front-end system 803 can provide multiple functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

At least one of the power amplifiers 811 and/or LNAs 812 is implemented with power detection in accordance with the teachings herein.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 8, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 8, the power management system 805 receives a battery voltage from the battery 808. The battery 808 can be any suitable battery for use in the mobile device 800, including, for example, a lithium-ion battery.

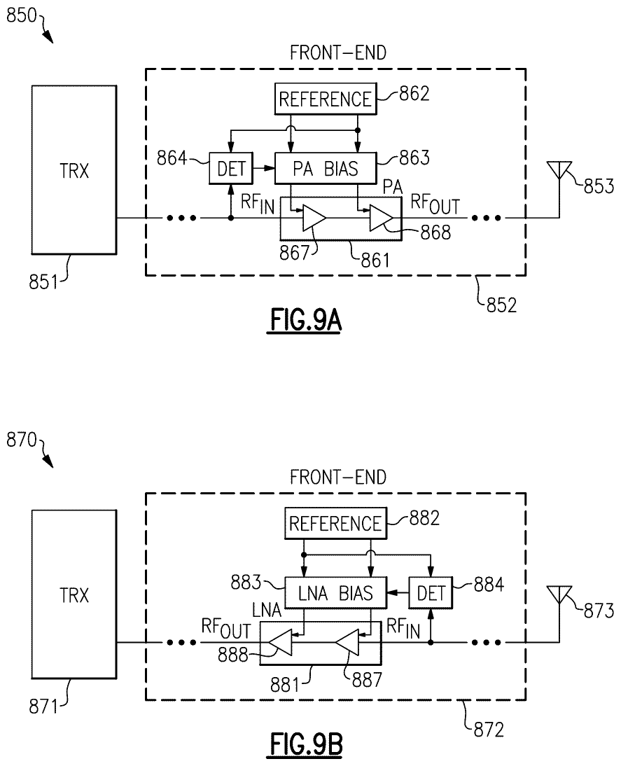

FIG. 9A is a schematic diagram of another embodiment of a mobile device 850. The mobile device 850 includes a transceiver 851, a front-end system 852, and an antenna 853.

In the illustrated embodiment, the transceiver 851 generates an RF input signal, which is provided to an RF input RF_{IN} of the front-end system 852. The front-end system 852 includes a power amplifier 861 that amplifies the RF input signal to generate an RF output signal that is provided to an RF output RF_{OUT} and transmitted by the antenna 853. The power amplifier 861 includes a first stage 867 biased by a first bias signal and a second stage 868 biased by a second bias signal. The front-end system 852 also includes a reference signal generator 862 that generates a first reference signal and a second reference signal, and a power amplifier bias circuit 863 that generates the first bias signal based on the first reference signal and the second bias signal based on the second reference signal. The front-end system 852 further includes a power detector 864 that generates a detection signal for the power amplifier bias circuit 863 based on sensing a power of the RF input signal. The power detector 864 is selectively enabled by the second reference signal.

The mobile device 850 depicts one example of providing ruggedness protection to a power amplifier in accordance with the teachings herein. Although one example of ruggedness protection is shown, any combination of features from the embodiments described herein can be used to provide ruggedness protection to the power amplifier 861.

FIG. 9B is a schematic diagram of another embodiment of a mobile device 870. The mobile device 870 includes a transceiver 871, a front-end system 872, and an antenna 873.

In the illustrated embodiment, the antenna 873 generates an RF input signal in response to receiving a radio wave. The front-end system 872 includes a low noise amplifier 881 that amplifies the RF input signal to generate an RF output signal that is provided to the transceiver 871. The low noise amplifier 881 includes a first stage 887 biased by a first bias signal and a second stage 888 biased by a second bias signal. The front-end system 872 further includes a reference signal generator 882 that generates a first reference signal and a second reference signal, and a low noise amplifier bias circuit 883 that generates the first bias signal based on the first reference signal and the second bias signal based on the second reference signal. The power detector 884 generates a detection signal for the low noise amplifier bias circuit 883 based on sensing a power of the RF input signal. The power detector 884 is selectively enabled by the second reference signal.

The mobile device 870 depicts one example of providing ruggedness protection to a low noise amplifier in accordance with the teachings herein. Although one example of ruggedness protection is shown, any combination of features from the embodiments described herein can be used to provide ruggedness protection to the low noise amplifier 881.

### Applications

Some of the embodiments described above have provided examples in connection with mobile devices. However, the principles and advantages of the embodiments can be used for any other systems or apparatus that have needs for power amplifiers with signal limiting. Examples of such systems and apparatus include, but are not limited to, mobile phones, tablets, base stations, network access points, customer-premises equipment (CPE), laptops, wireless routers, and wearable electronics.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A mobile device comprising:
a transceiver configured to generate a radio frequency input signal; and
a front-end system including a power amplifier configured to amplify the radio frequency input signal and that includes a first stage biased by a first bias signal and a second stage biased by a second bias signal, the front-end system further including a reference signal generator configured to generate a first reference signal and a second reference signal, a power amplifier bias circuit configured to generate the first bias signal based on the first reference signal and the second bias signal based on the second reference signal, and a power detector that generates a detection signal based on sensing a power of the radio frequency input signal, the power detector selectively enabled by the second reference signal.

2. The mobile device of claim 1 wherein the power amplifier bias circuit disables at least one stage of the power amplifier in response to activation of the detection signal to provide ruggedness protection.

3. The mobile device of claim 1 wherein the power amplifier is operable in a plurality of operating modes, and the power amplifier bias circuit processes the detection signal to set an operating mode of the power amplifier to a selected operating mode chosen from the plurality of operating modes.

4. The mobile device of claim 1 wherein the first stage is an input stage.

5. The mobile device of claim 4 wherein the second stage is an output stage.

6. The mobile device of claim 4 wherein the second stage is an intermediate stage connected between the input stage and an output stage of the power amplifier.

7. The mobile device of claim 1 wherein the power amplifier bias circuit includes a pull-down transistor configured to pull-down at least one of the first bias signal or the second bias signal in response to activation of the detection signal.

8. The mobile device of claim 1 wherein the power detector activates the detection signal in response to the power of the radio frequency input signal exceeding a power threshold.

9. The mobile device of claim 8 wherein a value of the power threshold changes with temperature to provide temperature compensation.

10. The mobile device of claim 8 wherein a value of the power threshold changes with a supply voltage of the power amplifier to provide supply voltage compensation.

11. A method of power detection in a power amplifier system, the method comprising:
amplifying a radio frequency input signal using a power amplifier that includes a first stage biased by a first bias signal and a second stage biased by a second bias signal;
generating a first reference signal and a second reference signal using a reference signal generator;
generating the first bias signal based on the first reference signal and generating the second bias signal based on the second reference signal using a power amplifier bias circuit;
generating a detection signal based on sensing a power of the radio frequency input signal using a power detector; and
selectively enabling the power detector using the second reference signal.

12. The method of claim 11 further comprising using the power amplifier bias circuit to disable at least one stage of the power amplifier in response to activation of the detection signal to provide ruggedness protection.

13. The method of claim 11 wherein the power amplifier is operable in a plurality of operating modes, the method further comprising processing the detection signal to set an operating mode of the power amplifier to a selected operating mode chosen from the plurality of operating modes.

14. A power amplifier system comprising:
a power amplifier configured to amplify a radio frequency input signal, the power amplifier including a first stage biased by a first bias signal and a second stage biased by a second bias signal;
a reference signal generator configured to generate a first reference signal and a second reference signal;
a power amplifier bias circuit configured to generate the first bias signal based on the first reference signal and the second bias signal based on the second reference signal; and
a power detector that generates a detection signal based on sensing a power of the radio frequency input signal, the power detector selectively enabled by the second reference signal.

15. The power amplifier system of claim 14 wherein the power amplifier bias circuit disables at least one stage of the power amplifier in response to activation of the detection signal to provide ruggedness protection.

16. The power amplifier system of claim 14 wherein the power amplifier is operable in a plurality of operating modes, and the power amplifier bias circuit processes the detection signal to set an operating mode of the power amplifier to a selected operating mode chosen from the plurality of operating modes.

17. The power amplifier system of claim 14 wherein the first stage is an input stage.

18. The power amplifier system of claim 17 wherein the second stage is an output stage.

19. The power amplifier system of claim 14 wherein the power amplifier bias circuit includes a pull-down transistor configured to pull-down at least one of the first bias signal or the second bias signal in response to activation of the detection signal.

20. The power amplifier system of claim 14 wherein the power detector activates the detection signal in response to the power of the radio frequency input signal exceeding a power threshold.

21.-40. (canceled)
